(19) United States
(12) Patent Application Publication
(10) Pub. No.: US 2008/0087326 A1
(43) Pub. Date: Apr. 17, 2008

(54) LIGHT-HARVESTING ANTENNAE FOR ORGANIC SOLAR CELLS

(76) Inventors: Gregory Denton Scholes, Toronto (CA); Tieneke Emily Dykstra, Toronto (CA); Xiujuan Yang, London (CA)

Correspondence Address: MILLER THOMPSON, LLP, Scotia Plaza, 40 King Street West, Suite 5800, TORONTO, ON, M5H 3S1, CA

(21) Appl. No.: 11/758,348

(22) Filed: Jun. 5, 2007

Related U.S. Application Data
(60) Provisional application No. 60/810,638, filed on Jun. 5, 2006.

(51) Int. Cl. H01L 31/04

(52) U.S. Cl. 136/263; 136/252

(57) ABSTRACT

An antenna layer is provided separate from an active layer in a solar cell device based on organic materials, enabling improved energy conversion in the solar cell devices by increasing the efficiency and spectral cross-section for the capture of incident light. The antenna layer may be anthracene or an anthracene derivative, for example. The antenna layer is operable to harvest light and transfer captured excitation energy to the active layer of the solar cell device using an energy transfer mechanism, wherein the charge separation and/or the formation of free carriers takes place. The antenna layer also limits the ultraviolet exposure of the active layer thus extending the operating life of the solar cell. The active layer and the antenna layer of a solar cell device may be independently optimized such that there is an increased spectral range and/or cross-section of light absorption and thus a higher photovoltaic efficiency.

### PRIORITY

This application claims the benefit of U.S. Provisional Patent Application No. 60/810,638, filed on 5 Jun. 2006.

### FIELD OF THE INVENTION

The present invention relates to photovoltaic cells. The present invention more particularly relates to antennae for organic photovoltaic cells.

### BACKGROUND OF THE INVENTION

Interest in polymer-based organic photovoltaic cells has increased over the past few years, as developments in technology, device engineering and the choice and range of materials used has improved solar energy conversion efficiencies above a 3% yield. Recent fundamental advances include polymer blends for improving charge separation, semiconductor nanocrystal-doped conjugated polymers, and fullerene-doped materials. Generally speaking, the advantages of organic solar cells lie in their ease of fabrication and subsequent low production costs, as well as the potential to exploit a vast array of possible chemical structures and functionalities of organic materials.

Currently the major disadvantages of organic solar cells relate to their low conversion efficiency, durability of organic materials when photo-excited continuously for long periods of time, the efficiency of photo-induced charge separation as well as electron and hole mobilities, and the fact that many of the active layers currently under investigation do not absorb the full range of light as is made available by the solar spectrum. Thus, an additional optimization is the incorporation of an extrinsic antenna to improve the spectral and spatial cross-section for light absorption.

Such antennae are ubiquitous in natural photosynthetic systems. Replicating the complex pigment/protein interactions in photosynthetic proteins for use in man-made solar light harvesting devices is in general very complicated. However, the design principles of photosynthetic light harvesting can be used as inspiration in tackling the idea of artificial antenna systems. In particular, systems can be developed which rely on the resonance energy transfer (RET) phenomena (also known as electronic energy transfer “EET”), a ubiquitous photophysical process whereby an electronically excited “donor” molecule transfers its excitation energy to an “acceptor” molecule by a non-trivial mechanism such that the excited state lifetime of the donor is diminished because of the transfer of excitation to the acceptor. It is also known that energy transfer in this manner may be made more efficient by utilization of the collective properties of aggregated molecules. (Scholes, G. D. Long-range resonance energy transfer in molecular systems. Annu. Rev. Phys. Chem. 54, 57 (2003); Fleming, G. R. & Scholes, G. D. Quantum mechanics for plants. Nature 431, 256 (2004)).

The state-of-the-art in organic solar cell technology have achieved efficiencies of above 3%, and 10% is the longer term goal. However, fundamental understanding of the physics that underlies the various processes and limits efficiencies in such devices is poor, hindering advancement. Major shortcomings in these organic materials, such as low stability, poor carrier mobility and weak absorption in the red have been addressed and incremental improvements are being made through optimization of materials and device design. In particular, four types of organic-based solar cells have shown great promise: (i) single layer and heterojunction solar cells using doped pentacene single crystals; (ii) planar multilayer heterojunction devices made by vacuum deposition of thin films of small molecules; (iii) blends of polyphenylenevinylene (PPV) and fullerene (C₆₀) derivatives; and (iv) solid state hybrid organic-inorganic dye sensitized solar cells (DSSCs). The latter utilizes a dye as light absorber, which injects an electron into the nanocrystalline metal oxide electron transporting film, with the hole transporting medium a liquid or organic material.

Light harvesting has become one of the fundamental goals of current research in improving the efficiency and photocurrent generation in these organic solar cell devices. Strategies have involved synthesizing polymers with broader absorption features that venture more towards the red, replacing electron transporting polymers in a blend with polycrystalline organic dyes with wider absorption bands, further development of dyes and dye combinations for use in DSSCs and the utilization of trapping structures to improve photon capture where absorption is weak.

It is known that the limits to the power conversion efficiency of any organic solar cell is determined by the product of four quantum efficiencies, namely absorption efficiency, exciton diffusion efficiency, charge transfer efficiency and charge collection efficiency. Where the charge transfer and collection efficiencies have been found to be close to 100% at donor/acceptor interfaces in thin-film molecular organic semiconductor photovoltaic cells, the low absorption and exciton diffusion efficiencies have been the main reason for the relatively small overall solar conversion efficiencies of such devices. The exciton diffusion efficiencies have been increased by employing a bulk heterojunction or double heterostructure, using materials with long range order and an increased understanding of the role that film morphology plays.

Increasing the absorption of light and utilizing the absorbed energy more effectively is another important aspect of organic solar cell development. Pertinent examples include tandem cells, attaching dye-moeities for intramolecular energy transfer to C₆₀ and the use of dendrimer type antennae for artificial photosynthesis. Light harvesting approaches that have been shown to work for organic-inorganic hybrid cells are based mainly on the TiO₂ Grätzel cell. Dye sensitization, the use of up- and down-converted phosphor layers, photonic crystals, anti-reflective coatings and the use of nanorods or nanowires has extended the amount and range of light that can be absorbed by these devices.

It should be understood that it is important that any new design elements that are implemented with a solar cell does not counter the basic functioning of the device, i.e. the absorption of light and subsequent efficient separation and collection of electrons and holes.

In light of the challenges in the design of solar cells, many different devices have been proposed. For example, U.S. Patent Application No. 2005/0022865 to Robeson et al. describes a light harvesting material mixed with other polymers such as hole transport or electron transport materials into a single phase.

U.S. Pat. No. 4,281,053 to Tang Ching describes a specific bi-layer PV device structure containing an electron donor layer and a layer comprised of a photoconductive polycyclic aromatic dye.

Canadian Patent No. 1,229,221 to Bolton and Guillet describes a photovoltaic cell including a conductive substrate, a layer of organic P-N junction molecules, and a polymer antenna containing “sensitizers” for capturing light, and capable of conveying the electrons therethrough. However, this configuration is relatively inefficient for antenna layers of more than 10 nm thickness because it relies on an incoherent hopping mechanism.

U.S. Pat. No. 6,407,330 to Lindsey et al. describes the use of a layer of “light harvesting rods” to capture additional light and transfer its energy to the active layer. The mechanism described is one of charge separation as a result of the specific molecular structure of the rods.

Furthermore, U.S. Pat. No. 4,629,821 to Bronstein-Bonte et al. describes the use of an additional layer of a dye molecule to absorb light at short wavelengths and re-emit it at the longer wavelengths to which the active layer is more sensitive. However, this down-conversion mechanism has generally low energy transfer efficiency and consequently has limited applicability to, for example, the Si PV cells described therein.

Moreover, U.S. Patent Application No. 2005/0211293 to Enomoto et al. describes a photoelectric transfer element or PV structure comprising a mixture of a conducting polymer, an electron acceptor material and porphyrin aggregate as antenna. The porphyrin absorbs light at long wavelengths and generates photoelectrons for direct transfer to the electron acceptor.

On the basis of the foregoing, what is needed is a simple and relatively inexpensive method and antenna device for increasing the cross-section of spectral absorption in organic solar cells, thereby increasing the solar energy conversion efficiency of the cell. There is a further need for an antenna device which absorbs light in a spectral window where the absorption of the basic device is low. There is a further need for an antenna device that boosts the overall absorbance of a solar cell device, which is particularly important for very thin devices, a characteristic of most organic photovoltaics. There is yet a further need for a method and an antenna device that absorbs strongly in the UV region of the incident spectrum and thereby impedes degradation of polymers used in solar cells.

### SUMMARY OF THE INVENTION

The present invention is directed at increasing the light-harvesting capabilities of solar cells based on organic materials such as conjugated polymers.

In an aspect of the present invention, an antenna may be a cluster, microcrystal, or film of molecules that harvests light and transfers the captured excitation energy to an active layer of a solar cell device using resonance energy transfer (“RET”), wherein the charge separation and/or the formation of free carriers takes place. The antenna may be either in direct contact with the active layer or it may be external to a contact and connected by an intermediary, e.g., via a metal electrode. The molecular aggregate of the antenna layer increases both the effectiveness of light absorption as well as the efficiency of RET to the active layer.

Preferably, the antenna consists of an ordered or aggregated assembly of molecules of a suitable material. An example is anthracene or an anthracene derivative. The aggregation generally improves the efficiency of the cell by enabling collective processes to redistribute the excitation energy most rapidly from the antenna to the active layer. Because the transfer of excitation from the antenna layer to the active layer proceeds by RET, no photons are generated in this step.

The light-harvesting molecules that comprise the antenna are not dispersed throughout the active layer, thereby avoiding interference with charge separation and carrier mobility in the active layer. This antenna may play secondary roles in assisting electron or hole transport as well as shielding the active layers from harmful UV radiation, thereby limiting photo-degradation.

In another aspect of the present invention, the active layer and the antenna may be independently optimized such that there is an increased spectral range and/or cross-section of light absorption and thus a higher photovoltaic efficiency. In other words, the efficiency and cross-section for light absorption can be tuned fairly independently of optimizations that improve free carrier generation. For example, the spectral cross-section (i.e. the wavelength range for absorption) or absorption cross-section (i.e. the number of photons absorbed, which is generally proportional to the thickness) can be adjusted for the antenna using chemical substitution and processing variations.

Advantages of the present invention include: (a) improved energy conversion efficiency as measured using the AM1.5 incident solar spectrum; (b) improved efficiency of solar cells under low incident light conditions, for example in shaded, covered, or indoors environments; (c) improved efficiency for incident spectra different from AM1.5, for example northern latitudes on Earth, various types of indoor lighting, underwater, etc.; and (d) reduced photo-degradation of the active layers by reducing the UV exposure of the active layer.

### BRIEF DESCRIPTION OF THE DRAWINGS

A detailed description of one or more embodiments of the present invention are provided herein below by way of example only and with reference to the following drawings, in which:

FIG. 1 illustrates a representation of the RET phenomena;

FIG. 2 illustrates an embodiment of a light-harvesting antenna;

FIG. 3 illustrates the molecular structures of antennae materials: anthracene (“ANT”), 9,10-dicholoroanthracene (“DCA”) and 9,10-dipenylanthracene (“DPA”), and the polymer, poly[2-methoxy,5-(2methyl-hexoxy)-1,4-phenylenevinylene] (“MEH-PPV”);

FIG. 4 illustrates device architecture of a photovoltaic cell;

FIG. 5 illustrates the fluorescence spectra of ANT (depicted by the dotted line), DCA (depicted by the dot-dash line), and DPA (depicted by the dash line) in acetonitrile and absorption spectra of MEH-PPV in chlorobenzene (depicted by the solid line);

FIG. 6 illustrates the absorption (upper panels) and fluorescence excitation (lower panels) spectra of three different embodiments of the present invention: (a) ANT antennae coupled with MEH-PPV active layer; (b) DCA antennae coupled with MEH-PPV active layer; and (c) DPA antennae coupled with MEH-PPV double active layers; and

FIG. 7 illustrates the fluorescence decay curves of preferred antenna materials with and without the MEH-PPV cell.

In the drawings, embodiments of the invention are illustrated by way of example. It is to be expressly understood that the description and drawings are only for the purpose of illustration and as an aid to understanding, and are not intended as a definition of the limits of the invention.

### DETAILED DESCRIPTION OF THE INVENTION

The present invention is directed at increasing energy conversion in organic solar cells by improving the efficiency, spectral cross-section, and absorbance for the capture of incident light.

The term “solar cell” as used herein refers to a photovoltaic device or photodetector that converts incident light into electrical potential or an electrical signal.

The term “efficiency” as used herein refers to energy conversion efficiency as defined by the ratio of the output electrical power of the device under illumination to the input power defined in a manner that is known.

The term “organic” as used herein refers to a solar cell in which the active layer is made of or contains a conjugated polymer, oligomer, dendrimer or other molecule where both absorption and charge transport are dominated by partly delocalized π and π* orbitals.

The term “active layer” as used herein refers to the part of a solar cell device in which charge separation takes place, i.e. the generation of free carriers that ultimately constitute photo-current.

The term “antenna” as used herein refers to a material (or materials) that absorb light and increases spectral cross-section.

The term “light-harvesting arrangement” as used herein refers to any configuration allowing energy transfer from an antenna layer to an active layer of a photovoltaic cell, whether that energy transfer is direct or via an intermediary, and is not meant as referring any particular arrangement, configuration, array or photovoltaic cell structure having these attributes.

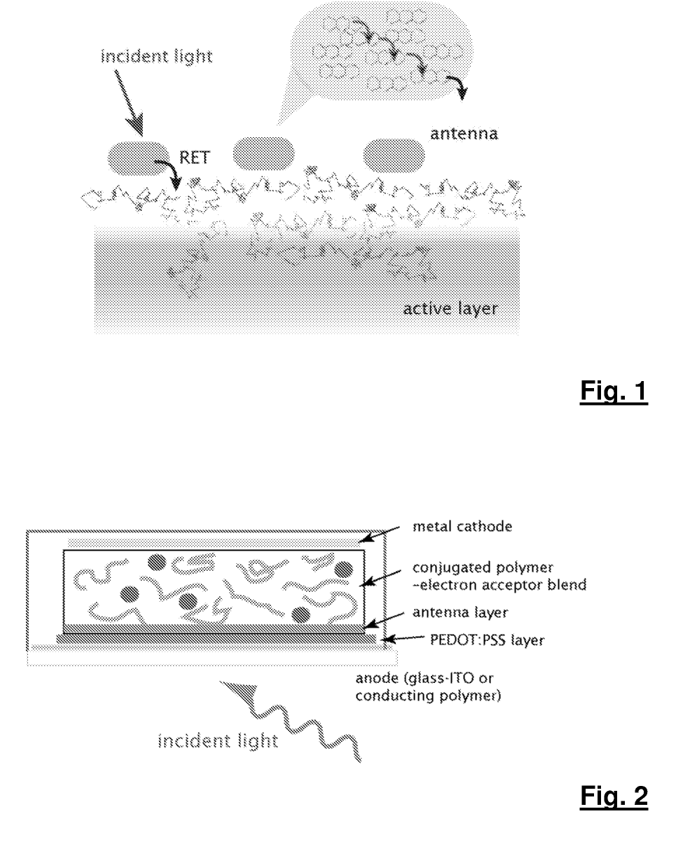

The term “resonance energy transfer”, or “RET”, as used herein refers to the process whereby an electronically excited “donor” molecule transfers its excitation energy to an “acceptor” molecule by a nontrivial mechanism (as opposed to uncorrelated donor emission-acceptor absorption events). Where RET occurs, the excited state lifetime of the donor is diminished because of the transfer of excitation to the acceptor. FIG. 1 depicts the movement of absorbed excitation energy, firstly through the antenna structure, then from the antenna to the conjugated polymer molecules in the active layer. In a bulk heterojunction solar cell, further RET occurs in the active layer until the electronic excitation encounters a site where charge separation occurs.

FIG. 2 depicts an embodiment of a light-harvesting antenna. In accordance with this particular implementation, an antenna layer is added to a solar cell in an arrangement to harvest incident light and to transfer that captured excitation energy by a resonance energy transfer mechanism with a quantum efficiency of >50% to an active layer, e.g., polymer-containing layer. The antenna may play secondary roles in assisting electron or hole transport as well as shielding the active layers from harmful UV radiation and thus limiting photo-degradation. The antenna layer may be made up of one or more organic materials such that a greater absorption range can be achieved and more incident light can be absorbed. Energy transfer between antenna molecules can occur before the excitation is trapped by the active layer.

An antenna in accordance with the present invention may contain a plurality of light absorbing molecules, grouped into a single structural unit. In that way, the light-harvesting molecules are not dispersed among the active layer, thereby interfering with charge separation and carrier mobility. Moreover, the light-absorbing molecules can function collectively to capture and redistribute light (it is said that light is absorbed into “exciton” states). These states have much higher absorption cross-sections than isolated molecules, so incident light is captured in a significantly greater yield. Furthermore, energy of absorbed photons can be transferred over large distances within the complex, thus being funnelled into the active layer on a time-scale much faster than the excited state lifetime. That, in turn, increases the yield of free carriers generated in the active layer by ensuring that the antenna is not “lossy” (photophysical processes competing with resonance energy transfer deplete the excited state population, converting excitation energy to thermal energy or photoluminescence emission).

The present invention is generally inspired by the manner in which photosynthetic organisms typically adapt to low-light intensities: they increase the number of light-absorbing molecules in their light-harvesting antenna complexes. That shows the importance of capturing photons in a highly-optimized solar energy conversion device.

The antenna layer of the present invention consists of a plurality of light absorbing molecules (e.g., between ˜8 and many tens of thousands or more), grouped into a single structural unit or several large subunits. The energy transfer from antenna layer to active layer uses the collective properties of these aggregated molecules. Interactions among the molecules that comprise the light-harvesting antenna permit absorbed light to be funnelled efficiently over long distances, where the usual energy transfer “hopping” process from one molecule to the next would be too slow to compete with the fluorescence lifetime of the antenna molecules. Thus energy transfer within the antenna, and from the antenna to the active layer, can therefore occur in the so-called “intermediate coupling” limit. That means that electronic states are coherent over several, or many, molecules that collectively comprise the “donor” or “acceptor”. A significance of utilizing this mechanism for energy collection and trapping in an organic solar cell is that the absorption cross-section of the antenna can be substantially increased over that possible otherwise. In other words, coherent effects increase the diffusion length of the excitation, allowing light-harvesting to be effective in larger antenna assemblies than taught in the prior art.

The energy transfer from the point of absorption into the antenna to the active layer uses the collective properties of aggregated molecules. The collective properties of interacting molecules in the antenna include any energy transfer process that increases the efficiency of energy transfer through the antenna and to the active layer compared to an incoherent hopping model (often referred to as Förster energy transfer).

An aspect of the present invention is that the antenna layer can be optimized independently from the active layer(s) of the device. By isolating the functions of light-harvesting (in the antenna complexes) and carrier generation (in the active layer), it is possible to optimize independently these process, since they are not necessarily interdependent. For example, the spectral cross-section (˜wavelength range for absorption) or absorption cross-section (˜thickness) can be adjusted for the antenna using chemical substitution and processing variations. The active layer can be changed, for example, in an organic heterojunction solar cell the electron acceptor in the polymer could be changed, without adversely affecting the light-harvesting function.

The antenna may be a separate layer in the device structure, or it may be organized in the device in a more complex fashion. Examples or the latter include islands of antenna dispersed in or around the active layer, or other such domains which function in the capacity of a light-harvesting antenna.

Advantageously, the antenna layer serves to protect the active layer of a photovoltaic cell. In general, organic solar cells are susceptible to degradation from ultraviolet light. The antenna of the present invention may be operable to absorb the damaging ultraviolet photons, thereby serving as a protective layer. Therefore, it should be understood that the antenna layer in accordance with the present invention serves two main functions: (i) to increase the efficiency of the solar cell; and (ii) to protect the organic active layer of solar cell from ultraviolet degradation.

In the examples described herein, anthracene is used as an antenna layer material. Anthracene is a model antenna chromophore (i.e. light-absorbing molecule) chosen because: (a) its absorption spectrum overlaps a window where the model conjugated polymer, MEH-PPV, does not absorb; and (b) its solubility properties make is suitable as an antenna layer for conjugated polymers. However, in principle, any light-absorbing molecule could be used for an antenna layer.

Advantageously, anthracene and its derivatives are relatively inexpensive thereby boosting the efficiency of the solar cell without the costs consequences of many of the techniques described in the prior, which have generally been prohibitive of widespread application.

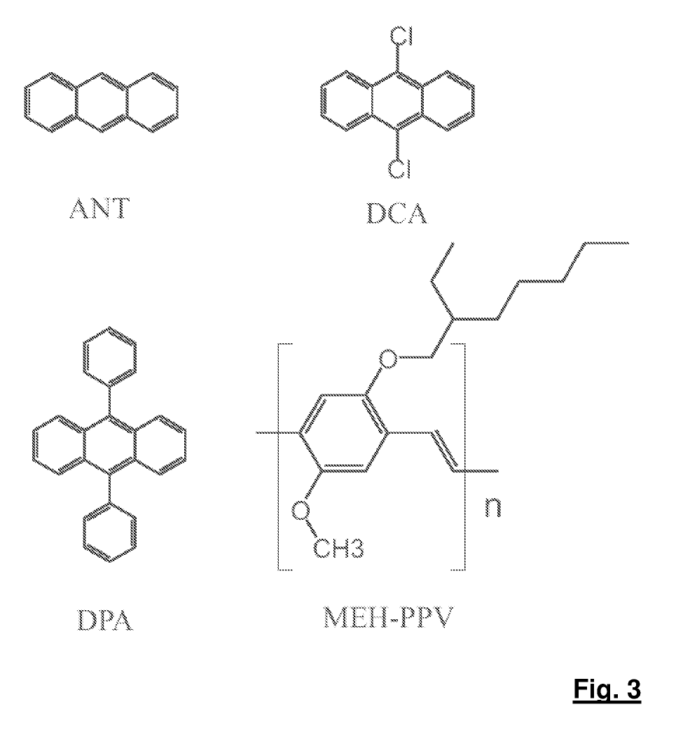

In particular embodiments of the present invention, the antenna layer can comprise anthracene (“ANT”), or an anthracene derivative such as 9,10-dichloroanthracene (“DCT”) or 9,10-diphenylanthracene (“DPT”), and can be implemented with a poly[2-methoxy,5-(2methyl-hexoxy)-1,4-phenylenevinylene] (“MEH-PPV”) conjugated polymer-based active layer. The molecular structures of these substances are depicted in FIG. 3. The antenna layers increase the capture of blue light by this device, though not restricted to any part of the spectrum specifically, as long as efficient resonance energy transfer is possible to the active layer. As such, this aspect of the present invention may be implemented to improve sensitivity in all spectral regions by judicial selection of other antennae, as long as there is good spectral overlap between the emission of the red-most antenna and the absorption of the active layer.

It will be appreciated by those skilled in the art that other variations of embodiments of antennae may also be practised without departing from the scope of the invention. The present invention may be further illustrated by the following non-limiting examples.

### EXAMPLE 1

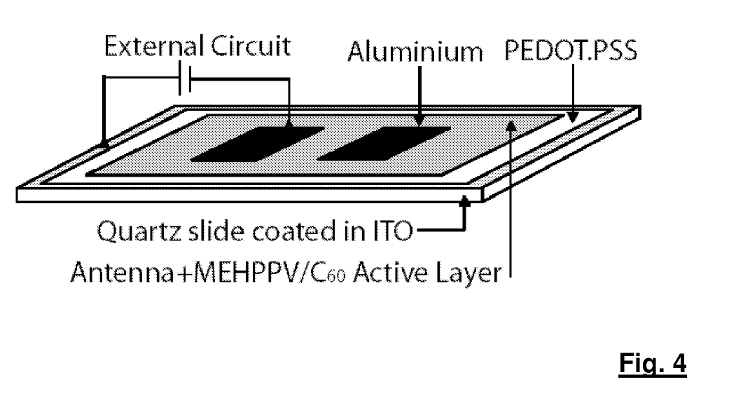

The light-harvesting efficiency of the present invention was demonstrated using systems consisting only of a clear quartz substrate, a bottom layer of MEH-PPV polymer, and a top antenna layer. These layers are prepared by sequentially spin coating MEH-PPV from chlorobenzene (˜250 nm) followed by spin-coating the antenna layer from acetonitrile solvent (˜150 nm). The film thicknesses and morphologies were determined by an ellipsometer and the surfaces were found to be somewhat rough, especially that of the antenna layer, where the anthracene and derivatives do not form a thin film, but rather recrystallize on the MEH-PPV. FIG. 4 illustrates the setup, with the organics spun on top of each other onto the quartz substrate. The order of the layers from bottom to top is quartz, ITO, PEDOT.PSS (a commonly used hole transport layer), antenna, blend of MEHPPV/C60 and aluminium electrode. The external circuit runs from the ITO anode to the aluminium cathode.

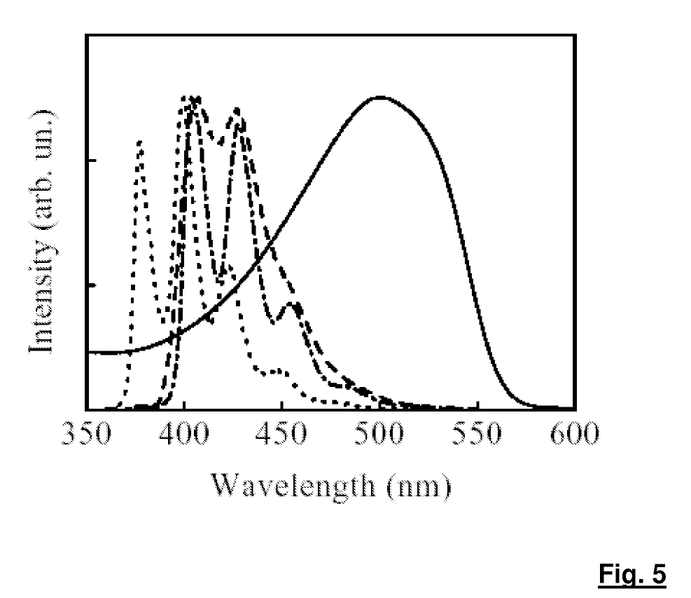

The spectral characteristics for light absorption and emission of antenna and polymer components of the model device are illustrated in FIG. 5. The fluorescence spectra of antennae and absorption spectrum of MEH-PPV in solution overlap well, which is important to ensure an efficient resonance energy transfer, by a Forster-type mechanism, of light absorbed by the antenna to the polymer. The RET mechanism involves the dipole transition moment of the donor coupling through a Coulombic interaction to that of the acceptor. The coupling provides a means to transfer the oscillation (excitation) non-radiatively from donor to acceptor.

This is in direct contrast to the mechanism at play in phosphor-based technologies where a donor emission-acceptor absorption mechanism is at play, in other words, a photon is emitted from the phosphor and is reabsorbed by the active layer. This limits the efficiency to less than 50% because fluorescence is emitted isotropically and those photons emitted in the direction away from the active layer (˜50%) are lost.

The efficient excitation energy transfer from the antenna layers, acting as the donors, to the polymer, acting as the acceptor, was observed using (a) fluorescence excitation spectra and (b) time resolved fluorescence measurements.

(a) Fluorescence Excitation Spectra

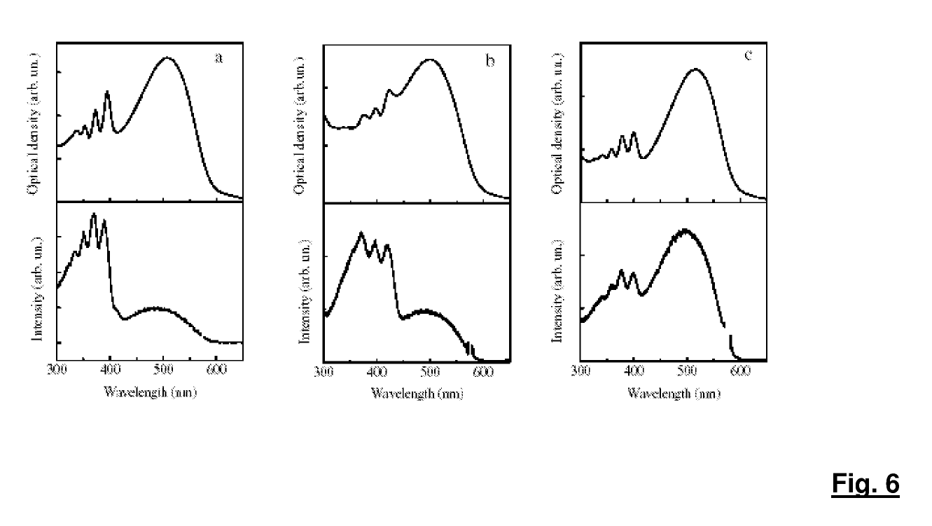

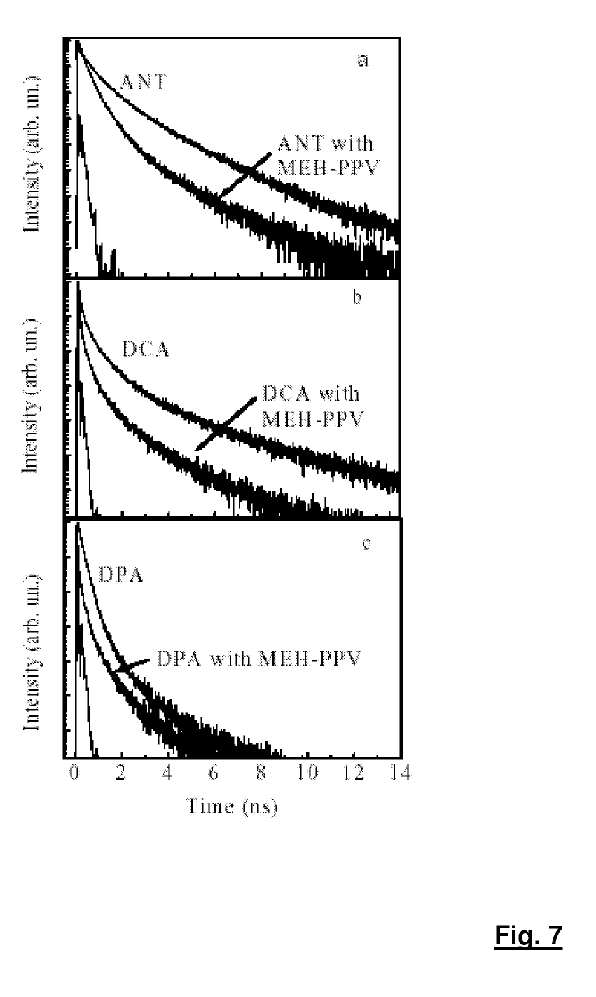

The absorption spectra of antenna/MEH-PPV double layer thin films are superimposed in the upper panels in FIG. 6 (a) Anthracene, (b) DCA and (c) DPA, where the relative optical density between antenna and MEH-PPV depends on the exact amount of material deposited during the spin coating and thus the layer thickness. The aggregate absorption spectrum of the antennae/MEH-PPV double-layer covers a spectrum ranging from 300 nm to approximately 550 nm, compared to 400 nm to 550 nm for MEH-PPV alone. The detection wavelength for the excitation measurement was 575 nm and is indicated by the gap in the spectrum. The excitation spectra of antennae/MEH-PPV films are shown in the lower panels of FIGS. 6 (a), (b) and (c), where the break in the trace is the wavelength of MEH-PPV emission that is being monitored (575 nm). In contrast to the absorption spectra, which reveal only the composition of the layers, the excitation spectra provide incisive evidence for energy transfer from the antenna layer to MEH-PPV. For example, at excitation wavelengths<400 nm for ANT/MEH-PPV, <430 nm for DCA/MEH-PPV and <420 nm for DPA/MEH-PPV double-layers, MEH-PPV fluorescence emission intensity is markedly greater than that from a film of MEH-PPV only, of comparable thickness. This experiment indicates very clearly that energy transfer has occurred, as in the absence of energy transfer an excitation spectrum should look similar to the absorption spectrum of the acceptor-only when the emission of the acceptor is monitored. The intensity of the antenna peaks<400 nm is very evident, showing that MEH-PPV emission has come from antenna absorption, illustrating that resonance energy transfer of excitation has occurred. The efficiency of this energy transfer depends crucially on spectral overlap between the donor antenna emission and the absorption of the acceptor MEH-PPV. It is clear from the presented data that the efficiency of energy transfer, as determined by the relative size of the antenna peaks in the excitation spectra, is greatest for the DCA/MEH-PPV combination (b), which corresponds to the combination where the spectral overlap is also the largest. Since the antennae are transparent above 450 nm, they do not disrupt the absorption of photons directly by MEH-PPV in that spectral region, and so by extending the spectral cross-section of light absorption, there is an increase in the overall photovoltaic efficiency. Concurrently, because the antenna layer absorbs much of the potentially harmful UV radiation that could cause damage to the polymer-based active layer, the solar device is protected from photo-degradation.

(b) Time Resolved Fluorescence Measurements:

To obtain further information about the efficiencies of energy transfer for each combination of antenna and MEH-PPV double-layer thin films, the time resolved fluorescence was measured for films with and without MEH-PPV. The samples were excited using 2 picosecond laser pulses at 370 nm by the second harmonic of a tunable mode-locked Ti-Sapphire laser and the fluorescence emission was time resolved by time-correlated single photon counting with 14 ps time resolution. The emission from the anthracene-containing samples was monitored at 400 nm and the emission from both the DCA- and DPA-containing samples was monitored at 440 nm, the choice of wavelength ensuring that only the antenna emission decay was measured, not that of MEH-PPV. FIG. 7 illustrates the molecular structures of antennae materials: anthracene (“ANT”), 9,10-dicholoroanthracene (“DCA”) and 9,10-dipenylanthracene (“DPA”), and the polymer, poly[2-methoxy,5-(2methyl-hexoxy)-1,4-phenylenevinylene] (“MEH-PPV”); illustrates the time resolved fluorescence decay data for antenna-only films compared to antenna/MEH-PPV double-layers, where the fluorescence decay of the antenna in these double layer thin films becomes faster compared to the antenna-only thin films because of excitation transfer to the MEH-PPV layer. The decay traces were fitted by multi-exponential global analysis, where a sum of three exponentials was required to fit the antenna-only data satisfactorily. For the antenna/MEH-PPV samples, one more timescale was needed to fit the data in addition to the same three decay times from the antenna only fit. This fourth timescale amounts to the additional kinetic process of energy transfer. The results of these fits are shown in Table 1 and show that the energy transfer times are 281 ps for anthracene→MEH-PPV, 28.6 ps for DCA→MEH-PPV and 37.2 ps for DPA→MEH-PPV. The reason the energy transfer times for DCA and DPA are so much faster is due to the much more favourable spectral overlaps. Nevertheless, even for anthracene, the energy transfer time is an order of magnitude greater than the fluorescence lifetime, which is assigned to be the slowest decay component, T1. Hence a good energy transfer efficiency can still be expected and this can be calculated using the fluorescence lifetime of the antenna donor (τ_{D}) and energy transfer time (τ_{DA}):

$${ϕ}_{ET} = 1 - \frac{{t}_{DA}}{{τ}_{D}} \qquad ( 1 )$$

Here φ_{ET} is the energy transfer efficiency, which amounts to the percentage of excitation transferred from donor to acceptor. For anthracene, the maximum efficiency attainable is 85%, and for DCA and DPA it is 99%. The actual efficiencies in the double layer films can be calculated by looking at the integrated intensity of the time-resolved fluorescence:

$${ϕ}_{ET} = 1 - \frac{{ϕ}_{DA}}{{ϕ}_{D}} = 1 - \frac{\int {I}_{DA} ( t ) ⅆ t}{\int {I}_{D} ( t ) ⅆ t} \qquad ( 2 )$$

where φ_{DA} is the quantum yield of the donor in the presence of an acceptor and φ_{D} is the quantum yield of the donor alone. The results are also presented in Table 1 and show that φ_{ET} is 45% for anthracene, 59% for DCA and 67% for the DPA antenna/MEH-PPV double layer thin films. Again, the efficiencies of DCA and DPA are higher due to the increased spectral overlap leading to faster energy transfer times and also the longer fluorescence lifetimes. It is clear that the actual efficiencies do not match the theoretical maximum efficiencies, and this is likely due to the inhomogeneity and morphology of the system, which means that not all the anthracene, DCA and DPA antenna molecules transfer their excitation to MEH-PPV. This too is evidenced in the global analysis, which clearly shows that there is still some antenna fluorescence in the double layer films.

TABLE 1
Fluorescence decay times, energy transfer times and energy transfer
efficiencies for the antennae/MEH-PPV double layer thin films as
measured by time resolved fluorescence (ANT = anthracene, DCA =
dichloroanthracene, DPA = diphenylanthracene).

| | ANT/ | DCA/ | DPA/ |
|---|---|---|---|
| Globally Fitted Decay Times | ANT/MEH-PPV | DCA/MEH-PPV | DPA/MEH-PPV |
| T1 (ns) shared | 1.857 | 3.530 | 3.736 |
| T2 (ps) shared | 561 | 852 | 1160 |
| T3 (ps) shared | 36 | 233 | 314 |
| T4 (ps) antenna/MEH-PPV only | 281 | 28.6 | 37.2 |
| Energy transfer efficiency, | 45 | 59 | 67 |
| antenna → MEH-PPV, φ_{ET}, % | | | |

### EXAMPLE 2

Organic solar cell devices were fabricated and tested as follows. All inch-squared ITO-coated glass cells were thoroughly cleaned by successive 5 minute sonications in detergent, deionized water, methanol, acetone, and isopropanol and were wiped and dried. Masks were applied to the cells using electrical tape about 2.5 mm into the entire perimeter of the cell. PEDOT.PSS was spin-coated on top of the ITO layer at a rate of 3000 rpm for 40 seconds, then 4000 rpm for the last 15 seconds, and left to cure at 150° C. in vacuo for 90 minutes. A second mask was then applied another 2.5 mm into the cell. A 0.6 wt. % 1:1 MEH-PPV(MW=900,000):C₆₀ derivative solution in 1,2,4-trichlorobenzene was prepared in an N₂ environment, after the solvent was purged with N₂ prior to addition to the solids. A saturated anthracene solution using methanol was also made, the methanol also purged with N₂ before addition to anthracene in an inert environment. Both solutions were kept in an N₂ environment in the dark at all times. For those cells containing anthracene, 0.1 ml was spin coated on top of the PEDOT.PSS layer at 1800 rpm, and left to dry for 10 minutes. A second layer was then applied with the same conditions. 0.125 ml of the MEHPPV/C₆₀ solution was spin coated on top of the anthracene at 3000 rpm for 40 seconds, then 15 seconds at 4000 rpm, and left in vacuum for over 5 hours at room temperature. All the spin coat steps were undertaken in a dry, N₂ environment, with minimal exposure to ambient light. A 150 nm thick aluminium layer was then applied using another mask to generate four central squares of surface area 64 mm² each. FIG. 4 shows the device architecture and layers of organics in this design. Silver paste was then dropped on top of the aluminium squares to ensure easier electrical contact and reduce the risk of short circuits by scratching of the Al layer by the cathode. The solar cells were tested for their response to light using a multimeter and then a homebuilt IV device in capacitor charging mode, where a SPEX fluorimeter provided the source of light.

What is claimed is:

1. A light-harvesting arrangement for a photovoltaic cell comprising:
an organic active layer; and
an antenna layer;
wherein the antenna layer is operable to increase the incident light absorbed by the active layer, including at wavelengths outside the spectral range of the organic active layer; and
wherein the antenna layer is connectable to the active layer for the transfer of incident light energy to the active layer through an energy transfer mechanism.

2. The light-harvesting arrangement of claim 1 wherein the energy transfer mechanism is an electronic energy transfer mechanism or a resonance energy transfer mechanism.

3. The light-harvesting arrangement of claim 2 wherein the energy transfer mechanism increases the efficiency of energy transfer between the antenna layer and the active layer compared to an incoherent hopping mechanism.

4. The light-harvesting arrangement of claim 3 wherein the antenna layer is connected to the active layer directly or through an intermediary.

5. The light-harvesting arrangement of claim 3 wherein the antenna layer is a substantially organic material.

6. The light-harvesting arrangement of claim 5 wherein the antenna layer is substantially anthracene, 9,10-dicholoroanthracene, or 9,10-dipenylanthracene.

7. The light-harvesting arrangement of claim 3 wherein the active layer is a conjugated polymer.

8. The light-harvesting arrangement of claim 3 wherein the antenna layer has a thickness of 50 to 500 nm.

9. The light-harvesting arrangement of claim 3 wherein the active layer has a thickness of 100 to 1000 nm.

10. The light-harvesting arrangement of claim 3 wherein there is more than one antenna layer.

11. The light-harvesting arrangement of claim 3 wherein the antenna layer limits the ultraviolet exposure of the active layer thereby limiting degradation of the active layer.

12. The light-harvesting arrangement of claim 3 wherein the antenna layer enhances efficiency of the solar cell.

13. The light-harvesting arrangement of claim 12 wherein the antenna layer enhances the efficiency of the solar cell in low-light situations.

14. The light-harvesting arrangement of claim 12 wherein the antenna layer enhances the efficiency of the solar cell in non-AM1.5 spectra.

15. A method of increasing spectral or spatial absorption cross-section of a photovoltaic cell having a base efficiency, the method comprising:
connecting an antenna layer to an organic active layer of the photovoltaic cell, wherein the antenna layer is operable to absorb light at a wavelength outside a spectral range of the active layer;
wherein the antenna layer absorbs energy from incident light and transfers the energy to the active layer by means of a energy transfer mechanism; and
whereby the base efficiency is increased.

16. The method of claim 15 further comprising selecting a material for the antenna layer to optimize the spectral absorption cross-section of the photovoltaic cell.

17. The method of claim 15 further comprising selecting a thickness of the antenna layer to optimize the spatial absorption cross-section of the photovoltaic cell.

18. A light-harvesting array for a photovoltaic cell comprising an antenna, wherein the antenna absorbs light at a wavelength outside a spectral range of an active layer of the photovoltaic cell and transfers incident light energy to the active layer through an electronic energy transfer mechanism that uses the collective properties of interacting molecules in the antenna.

19. The light-harvesting array of claim 18 wherein the electronic energy transfer mechanism increases the efficiency of energy transfer between the antenna layer and the active layer compared to an incoherent hopping mechanism.
